(19) United States
(12) Patent Application Publication
(10) Pub. No.: US 2026/0344199 A1
(43) Pub. Date: Oct. 29, 2026

(54) Display Substrate and Display Apparatus

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Dongdong SU, Beijing (CN); Yinhu HUANG, Beijing (CN); Yuhao LEE, Beijing (CN); Bingming FENG, Beijing (CN); Xiaobin SHEN, Beijing (CN); Yunlong LI, Beijing (CN); Huanhuan WANG, Beijing (CN); Lingang WEN, Beijing (CN); Fushuang ZHANG, Beijing (CN); Jianming ZOU, Beijing (CN); Gen LI, Beijing (CN); Bingfa YANG, Beijing (CN); Lei YUE, Beijing (CN); Dacheng ZHANG, Beijing (CN); Junkai YAN, Beijing (CN)

(21) Appl. No.: 18/840,506

(22) PCT Filed: Dec. 6, 2023
(86) PCT No.: PCT/CN2023/136840

§ 371 Date: Aug. 22, 2024

(51) Int. Cl. H10K 59/123; H10K 59/131; H10K 59/35; H10K 59/80

(52) U.S. Cl. CPC H10K 59/123; H10K 59/131; H10K 59/353; H10K 59/876

(57) ABSTRACT

A display substrate and a display apparatus are provided. The display substrate includes a base substrate (101), a reflection layer (305) and a light emitting composite layer (307). The reflection layer (305) has multiple first vias, and the light emitting composite layer (307) includes a first light emitting device (301). The display substrate further includes a first conductive structure (111), and the first light emitting device (301) is in contact with at least a portion of a surface of the first conductive structure (111); at least a portion of the first conductive structure (111) is located within a first via; the first conductive structure (111) includes at least two sections.

### CROSS-REFERENCE TO RELATED APPLICATION

The present application is a U.S. National Phase Entry of International Application No. PCT/CN2023/136840 having an international filing date of Dec. 6, 2023, contents of which are incorporated into the present application by reference.

### TECHNICAL FIELD

The present disclosure relates to, but is not limited to, the field of display technologies, and particularly relates to a display substrate and a display apparatus.

### BACKGROUND

Micro organic light emitting diodes (Micro OLEDs) are micro displays developed in recent years, and a silicon-based OLED is one of them. The silicon-based OLED can not only realize active addressing of pixels, but also can realize manufacturing of structures such as pixel drive circuits on a silicon-based substrate, which is conducive to reduce system volume and realize lightweight. Silicon-based OLEDs are manufactured using mature Complementary Metal Oxide Semiconductor (CMOS) integrated circuit process. Due to their advantages such as small size, high Pixels Per Inch (PPI), and high refresh rate, they are widely used in near-to-eye display fields of Virtual Reality (VR) or Augmented Reality (AR).

### SUMMARY

The following is a summary of subject matters described herein in detail. This summary is not intended to limit the protection scope of claims.

In one aspect, an embodiment of the present disclosure provides a display substrate. The display substrate includes a base substrate and a light emitting structure layer located on a side of the base substrate. The light emitting structure layer includes a reflection layer and a light emitting composite layer stacked sequentially in a direction away from the base substrate. The reflection layer has multiple first vias, and the light emitting composite layer includes a first light emitting device, a second light emitting device, and a third light emitting device arranged sequentially.

The light emitting structure layer further includes a first conductive structure, the first conductive structure is located between the light emitting composite layer and the base substrate, and the first light emitting device is in contact with at least a portion of a surface of the first conductive structure away from the base substrate. At least a portion of the first conductive structure is located within a first via. In a thickness direction of the display substrate, the first conductive structure includes at least two sections, an orthographic projection of a section close to the light emitting composite layer on a plane where the display substrate is located is located within an orthographic projection of a section adjacent to the section and away from the light emitting composite layer on the plane where the display substrate is located, and an area of the orthographic projection of the section close to the light emitting composite layer on the plane where the display substrate is located is less than an area of the orthographic projection of the section adjacent to the section and away from the light emitting composite layer on the plane where the display substrate is located.

In an exemplary embodiment, the display substrate includes multiple sub-pixels, and the multiple sub-pixels include at least a first sub-pixel, a second sub-pixel, and a third sub-pixel. The first sub-pixel includes the first light emitting device and is configured to emit light of a first color, and the second sub-pixel includes a second light emitting device and is configured to emit light of a second color. The third sub-pixel includes a third light emitting device and is configured to emit light of a third color, and each of the first color, the second color, and the third color is one of three primary colors.

The light emitting structure layer further includes a micro-cavity adjustment layer. The micro-cavity adjustment layer is located between the reflection layer and the light emitting composite layer. The micro-cavity adjustment layer is configured such that the first sub-pixel, the second sub-pixel, and the third sub-pixel have different micro-cavity cavity lengths.

In an exemplary embodiment, the micro-cavity adjustment layer includes a first adjustment part, a second adjustment part, and a third adjustment part arranged sequentially. The first adjustment part is configured such that the first sub-pixel has a first micro-cavity cavity length H1 and the first adjustment part has a first thickness h1. The second adjustment part is configured such that the second sub-pixel has a second micro-cavity cavity length H2 and the second adjustment part has a second thickness h2. The third adjustment part is configured such that the third sub-pixel has a third micro-cavity cavity length H3 and the third adjustment part has a third thickness h3, where H1>H2>H3, and h1>h2>h3.

In an exemplary embodiment, a thickness of the third adjustment part ranges from 200 angstroms to 600 angstroms.

In an exemplary embodiment, a thickness of the first adjustment part ranges from 1300 angstroms to 1700 angstroms and a thickness of the second adjustment part ranges from 1200 angstroms to 1600 angstroms.

In an exemplary embodiment, the micro-cavity adjustment layer has multiple second vias and the multiple second vias are provided in one-to-one correspondence with and in communication with the multiple first vias.

The first conductive structure includes two sections, the two sections are a first section and a second section respectively, and the second section is closer to the light emitting composite layer than the first section. The first section is located within a first via, and the second section is located within a second via.

In an exemplary embodiment, an orthographic projection of the first section on the plane where the display substrate is located has a first outer edge, and an orthographic projection of the second section on the plane where the display substrate is located has a second outer edge.

The first outer edge surrounds the second outer edge, there is a gap between the first outer edge and the second outer edge, and a range of the gap is greater than or equal to 0.04 micron and less than or equal to 0.1 micron.

In an exemplary embodiment, an orthographic projection of the second section on the plane where the display substrate is located coincides with an orthographic projection of the second via on the plane where the display substrate is located.

In an exemplary embodiment, a surface of the first section away from the base substrate is flush with a surface of the reflection layer away from the base substrate. Alternatively, a surface of the first section away from the base substrate is closer to the base substrate than a surface of the reflection layer away from the base substrate.

In an exemplary embodiment, the micro-cavity adjustment layer includes a first adjustment part, a second adjustment part, and a third adjustment part arranged sequentially, and thicknesses of the first adjustment part, the second adjustment part, and the third adjustment part are different.

The second adjustment part has multiple second vias, and the multiple second vias are provided in one-to-one correspondence with and in communication with the multiple first vias. The light emitting structure layer further includes a second conductive structure, the second conductive structure is located between the light emitting composite layer and the base substrate, and the second light emitting device is in contact with at least a portion of a surface of the second conductive structure away from the base substrate. At least a portion of the second conductive structure is located within the first via.

In an exemplary embodiment, the first light emitting device includes a first electrode, a first organic emitting layer, and a second electrode which are stacked, and the first electrode is closer to the base substrate than the second electrode. At least a portion of the first electrode is located on a side of the micro-cavity adjustment layer away from the base substrate.

In an exemplary embodiment, the micro-cavity adjustment layer has multiple second vias and the multiple second vias are provided in one-to-one correspondence with and in communication with the multiple first vias. The first electrode includes a first portion and a second portion that are connected; the first portion is located on a side of the micro-cavity adjustment layer away from the base substrate and the second portion is located within the second via.

In an exemplary embodiment, a thickness of the second portion is greater than or equal to 30% of a thickness of the first portion and less than or equal to the thickness of the first portion in a radial direction of the second via.

In an exemplary embodiment, a size of the second portion in the thickness direction of the display substrate does not exceed 50% of an aperture depth of the second via.

In an exemplary embodiment, the first electrode further includes a third portion, the third portion is located on a side of the micro-cavity adjustment layer away from the base substrate, and the third portion and the first portion are respectively located on two opposite sides of the second portion.

In an exemplary embodiment, an orthographic projection of the third portion on the plane where the display substrate is located has a size range in a radial direction of the second via greater than or equal to 0.04 micron and less than or equal to 0.1 micron.

In an exemplary embodiment, the light emitting structure layer further includes an isolation layer, the isolation layer is located within the first via, and the isolation layer is provided around the first conductive structure. An edge of an orthographic projection of the third portion on the plane where the display substrate is located close to the second light emitting device is located within a range of an orthographic projection of the isolation layer on the plane where the display substrate is located.

In an exemplary embodiment, the second light emitting device includes a third electrode, a second organic emitting layer, and a fourth electrode which are stacked, and the third electrode is closer to the base substrate than the fourth electrode.

There is a gap between an orthographic projection of the third portion on the plane where the display substrate is located and an orthographic projection of the third electrode on the plane where the display substrate is located, and a range of the gap is greater than or equal to 0.2 micron, and less than or equal to 0.5 micron.

In an exemplary embodiment, the gap is greater than a difference between an aperture of the first via and an aperture of the second via.

In an exemplary embodiment, an orthographic projection of the third portion on the plane where the display substrate is located is located within an orthographic projection of the first adjustment part on the plane where the display substrate is located, and an orthographic projection of the third electrode on the plane where the display substrate is located is located within an orthographic projection of the second adjustment part on the plane where the display substrate is located.

In an exemplary embodiment, the light emitting structure layer further includes an isolation layer, the isolation layer is located within the first via, and the isolation layer is provided around the first conductive structure.

In an exemplary embodiment, a surface of the isolation layer away from the base substrate is flush with a surface of the reflection layer away from the base substrate.

In an exemplary embodiment, a range of a ring width of the isolation layer is greater than or equal to 0.2 micron and less than or equal to 0.3 micron.

In an exemplary embodiment, the third thickness is greater than a maximum value of a ring width of the isolation layer.

In another aspect, an embodiment of the present disclosure provides a display apparatus. The display apparatus includes the display substrate described in any of the above embodiments.

Other aspects of the present disclosure may be comprehended after the drawings and the detailed description are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of one or more components in the drawings do not reflect actual scales, and are only intended to schematically describe contents of the present disclosure.

FIG. 1 is a test graph showing a relationship between refractive indices and wavelengths of two materials.

FIG. 2 is a test graph showing a relationship between extinction coefficients and wavelengths of two materials.

FIG. 3 is a schematic diagram of a structure of a display apparatus according to an embodiment of the present disclosure.

FIG. 4 is a schematic diagram of a planar structure of a display apparatus according to an embodiment of the present disclosure.

FIG. 5 is a schematic partial cross-sectional view of a structure of a display apparatus according to an embodiment of the present disclosure.

FIG. 6A is a first schematic partial cross-sectional view of a structure of a display substrate according to an embodiment of the present disclosure.

FIG. 6B is a partially enlarged schematic view at identification A in FIG. 6A.

FIG. 6C is a partially enlarged schematic cross-sectional view of a display substrate according to another embodiment of the present disclosure.

FIG. 7 is a second schematic partial cross-sectional view of a structure of a display substrate according to an embodiment of the present disclosure.

FIGS. 8A to 8N are schematic diagrams of a manufacturing process of a display substrate according to an embodiment of the present disclosure.

### REFERENCE SIGNS

101—base substrate, 102—drive circuit layer, 201—circuit structure layer, 202—connection layer, 202-1—first connection electrode, 202-2—second connection electrode, 202-3—third connection electrode;
103—light emitting structure layer, 301—first light emitting device, 301-1—first electrode, 301a—first portion, 301b—second portion, 301c—third portion, 301-2—second electrode, 301-3—first organic emitting layer, 302—second light emitting device, 302-3—third electrode, 302-4—fourth electrode, 302-5—second organic emitting layer, 303—third light emitting device, 303-5—fifth electrode, 303-6—sixth electrode, 303-7—third organic emitting layer, 304—insulation layer, 305—reflection layer, 305-1—first reflection electrode, 305-2—second reflection electrode, 305-3—third reflection electrode;
306—micro-cavity adjustment layer, 306-1—first adjustment part, 306-2—second adjustment part, 306-3—third adjustment part, 307—light emitting composite layer, 308—pixel definition layer, 308a—partition part, 308-1—first sub-layer, 308-2—second sub-layer, 308-3—third sub-layer, 309—isolation layer; 111—first conductive structure, 111-1—first section, 111-2—second section, 112—second conductive structure, 113—third conductive structure;
104—first encapsulation layer, 105—color film structure layer, 106—second encapsulation layer, 107—cover plate layer, 10—photoresist pattern, 11—first conductive thin film, 12—second conductive thin film, 13—third conductive thin film, 14—metal wiring layer, 15—second insulation thin film, 21—first adjustment layer, 22—second adjustment layer, 23-1—initial pattern of third adjustment layer, 23—third adjustment layer.

### DETAILED DESCRIPTION

Embodiments of the present disclosure will be described in detail herein with reference to the drawings. Implementations may be implemented in various forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description and simplification of the description only, but do not indicate or imply that the referred apparatus or element must have a particular orientation, or is constructed and operate in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, “electric connection” includes a case where constituent elements are connected through an element with a certain electrical action. An “element with a certain electrical action” is not particularly limited as long as electrical signals may be transmitted between the connected constituent elements. Examples of the “element with the certain electrical action” not only include electrodes and wirings, but also include switching elements such as transistors, resistors, inductors, capacitors, other elements with one or more functions, etc.

In the present disclosure, a transistor refers to an element including at least three terminals, i.e., a gate electrode, a drain electrode, and a source electrode. The transistor has a channel region between the drain electrode (drain electrode terminal, drain area, or drain) and the source electrode (source electrode terminal, source area, or source), and a current can flow through the drain electrode, the channel region, and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” or “approximately” refers to that a boundary is defined not so strictly and numerical values within process and measurement error ranges are allowed.

Triangle, rectangle, trapezoid, pentagon, hexagon or the like in the present disclosure are not strictly defined, and they may be approximate triangle, rectangle, trapezoid, pentagon, hexagon, etc. There may be some small deformations caused by tolerance, and there may be chamfer, arc edge, deformation, etc.

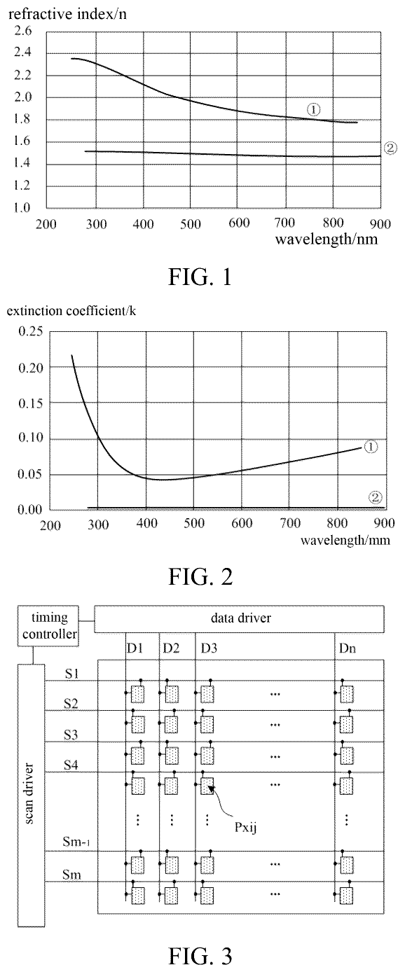

A top emission micro-cavity OLED display apparatus mainly realizes a full-color display effect through a micro-resonant cavity effect. The micro-resonant cavity effect refers to an optical interference effect that occurs inside an OLED device. To realize the micro-resonant cavity effect, it is necessary to make a half-transparent and half-reflective half-mirror at a light outlet of a device. When photons are emitted from a light emitting layer, mutual interference occurs between an emission anode and a half-mirror, resulting in light interference phenomenon. Only certain wavelengths of light will be enhanced, and some light will be weakened, so a half-height width of light waves will further be narrowed. Micro-cavity structures are generally divided into weak micro-cavity structures and strong micro-cavity structures. In the weak micro-cavity structures, cavity lengths of different sub-pixels are equal, so weak micro-cavity structures cannot maximize the use of micro-resonant cavity effects to improve light efficiency. In the strong micro-cavity structures, cavity lengths of different sub-pixels are not equal, and the light efficiency may be improved by about 3 times by using the micro-resonant cavity effect. There are two main ways to realize a strong micro-cavity structure, one is to thicken the electrode, and the other is to set up an adjustment layer. A material of the electrode is usually indium tin oxide (ITO), and a material of the adjustment layer is usually silicon oxide (SiOₓ). As shown in FIGS. 1 and 2, a curve marked \textcircled{1} represents a test curve of indium tin oxide (ITO), and a curve marked \textcircled{2} represents a test curve of silicon oxide (SiOₓ). A refractive index and an extinction coefficient of indium tin oxide (ITO) both exceed a refractive index and an extinction coefficient of silicon oxide (SiOₓ), so a use of thickened electrodes has a greater impact on a micro-cavity sensitive device (B Stack), which will cause a certain proportion of blue outlet light loss, and affect a maximum white light brightness.

An embodiment of the present disclosure provides a display substrate, including a base substrate and a light emitting structure layer located on a side of the base substrate. The light emitting structure layer includes a reflection layer and a light emitting composite layer stacked sequentially in a direction away from the base substrate. The reflection layer has multiple first vias, and the light emitting composite layer includes a first light emitting device, a second light emitting device, and a third light emitting device arranged sequentially.

The light emitting structure layer further includes a first conductive structure, the first conductive structure is located between the light emitting composite layer and the base substrate, and the first light emitting device is in contact with at least a portion of a surface of the first conductive structure away from the base substrate. At least a portion of the first conductive structure is located within a first via. Along a thickness direction of the display substrate, the first conductive structure includes at least two sections. An orthographic projection of a section close to the light emitting composite layer on a plane where the display substrate is located is located within an orthographic projection of a section adjacent to this section and away from the light emitting composite layer on the plane where the display substrate is located, and an area of the orthographic projection of the section close to the light emitting composite layer on the plane where the display substrate is located is less than an area of the orthographic projection of the section adjacent to this section and away from the light emitting composite layer on the plane where the display substrate is located.

In a display substrate provided by an embodiment of the present disclosure, the first conductive structure is designed with a variable cross-section. In this way, it is conducive to increasing a gap between a section of the first conductive structure close to the light emitting composite layer and an anode of the second light emitting device, thereby avoiding electrical crosstalk between the first light emitting device and the second light emitting device, and improving a reliability of the electrical connection of the display substrate.

FIG. 3 is a schematic diagram of a structure of a display apparatus according to an embodiment of the present disclosure. As shown in FIG. 3, an OLED display apparatus may include a timing controller, a data driver, a scan driver, and a pixel array. The timing controller is connected with the data driver and the scan driver respectively, the data driver is connected with multiple data signal lines (D1 to Dn) respectively, and the scan driver is connected with multiple scan signal lines (S1 to Sm) respectively. The pixel array may include multiple sub-pixels Pxij. Each sub-pixel Pxij may be connected to a corresponding data signal line and a corresponding scan signal line, and i and j may be natural numbers. At least one sub-pixel Pxij may include at least a circuit unit and a display unit. The circuit unit may include at least a pixel drive circuit connected with a scan signal line and a data signal line, respectively. The display unit may include at least a light emitting device connected with the pixel drive circuit of the circuit unit, and the sub-pixel Pxij may refer to a sub-pixel in which a pixel drive circuit is connected with an i-th scan signal line and a j-th data signal line. In an exemplary embodiment, the timing controller may provide a control signal and a gray scale value suitable for the specification of the data driver to the data driver, and may provide a scan start signal, a clock signal suitable for the specification of the scan driver and the like to the scan driver. The data driver may generate data voltages to be provided to the data signal lines D1, D2, D3, . . . , and Dn using the gray scale value and the control signal that are received from the timing controller. For example, the data driver may sample the gray scale value using the clock signal and apply a data voltage corresponding to the gray scale value to the data signal lines D1 to Dn by taking a pixel column as a unit, wherein n may be a natural number. The scan driver may generate scan signals to be provided to the scan signal lines S1, S2, S3, . . . , and Sm by receiving the clock signal and the scan start signal or the like from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting scan start signals provided in a form of an on-level pulse to a next-stage circuit under control of the clock signal, wherein m may be a natural number. In an exemplary implementation, the pixel array may be provided on the display substrate.

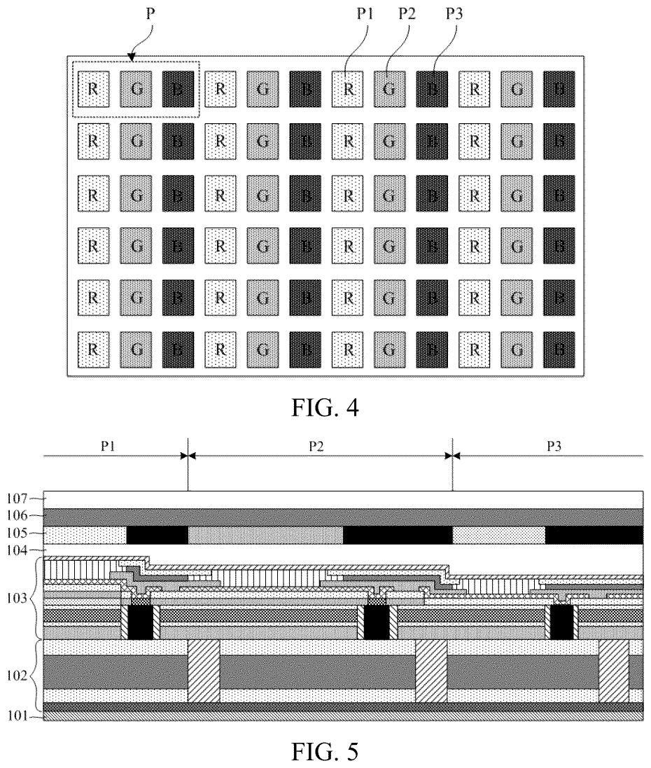

FIG. 4 is a schematic diagram of a planar structure of a display apparatus according to an embodiment of the present disclosure. As shown in FIG. 4, the display apparatus may include multiple pixel units P arranged in a matrix. At least one pixel unit P may include multiple sub-pixels, the multiple sub-pixels may at least include a first sub-pixel P1 emitting light of a first color, a second sub-pixel P2 emitting light of a second color, and a third sub-pixel P3 emitting light of a third color. The three sub-pixels may each include a pixel drive circuit and a light emitting device. The pixel drive circuit in the sub-pixel is respectively connected to a scan signal line and a data signal line, and the pixel drive circuit is configured to receive a data voltage transmitted by the data signal line and output a corresponding current to the light emitting device, under a control of the scan signal line. The light emitting device in the sub-pixel is connected to a pixel drive circuit of a sub-pixel where the light emitting device is located, and is configured to emit light with a corresponding brightness in response to a current output by the pixel drive circuit of the sub-pixel where the light emitting device is located.

In an exemplary embodiment, the first sub-pixel P1 may be a red sub-pixel emitting red (R) light, the second sub-pixel P2 may be a green sub-pixel emitting green (G) light, and the third sub-pixel P3 may be a blue sub-pixel emitting blue (B) light. In an embodiment of the present disclosure, red may also be referred to as the first color, green may also be referred to as the second color, and blue may also be referred to as the third color. In an exemplary implementation, a shape of a sub-pixel may be any one of a triangle, a rectangle, a rhombus, a trapezoid, a parallelogram, a pentagon, and a hexagon, etc., and the multiple sub-pixels may be arranged side by side in a horizontal direction, side by side in a vertical direction, in a shape of an square, or in a diamond shape, etc., which is not limited in the present disclosure.

FIG. 5 is a schematic partial cross-sectional view of a structure of a display apparatus according to an embodiment of the present disclosure, and illustrates a structure in which a full-color display is realized by means of a white light and a color film. As shown in FIG. 5, only taking a case in which one pixel unit is illustrated as an example, the display apparatus may include a display substrate and a first encapsulation layer 104, a color film structure layer 105, a second encapsulation layer 106, and a cover plate layer 107 disposed sequentially on a side of the display substrate. The display substrate may include a base substrate 101, a drive circuit layer 102 provided on the base substrate 101, and a light emitting structure layer 103 provided on a side of the drive circuit layer 102 away from the base substrate 101. In some possible implementations, the display apparatus may further include other film layers, and the present disclosure is not limited thereto.

In an exemplary embodiment, the base substrate 101 may be a Silicon-On-Insulator (SOI) base substrate. The drive circuit layer 102 may be fabricated on the base substrate 101 by a silicon semiconductor process (e.g., a CMOS process), and the drive circuit layer 102 may include multiple circuit units, the circuit units may include at least a pixel drive circuit, the pixel drive circuit is connected to a scan signal line and a data signal line, and the pixel drive circuit may include multiple transistors and a storage capacitor. A transistor may include a gate electrode, a first pole and a second pole. The gate electrode, the first pole and the second pole may be connected respectively to corresponding connection electrodes through vias filled with tungsten metal (i.e., tungsten via, W-via), and may be connected to other electrical structures (e.g., wires) through the connection electrodes.

In an exemplary embodiment, the light emitting structure layer 103 may include multiple light emitting devices, and a light emitting device may at least include a first electrode, an organic emitting layer, and a second electrode. The first electrode may be connected to a second pole of the transistor through a connection electrode, the organic emitting layer may be connected to the first electrode, the second electrode may be connected to the organic emitting layer, the second electrode may be connected to a second power supply line, and the organic emitting layer may emit light under the drive of the first electrode and the second electrode. For example, the first electrode may be an anode of the light emitting device, and the second electrode may be a cathode of the light emitting device. In an exemplary implementation, the organic emitting layer may include an Emitting Layer (EML) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In some possible implementations, for a light emitting device emitting white light, organic emitting layers of all sub-pixels may be a common layer connected together.

In an exemplary embodiment, the first encapsulation layer 104 and the second encapsulation layer 106 may adopt a Thin Film Encapsulation (TFE) mode, which may ensure that external water vapor cannot enter the light emitting structure layer. The cover plate layer 107 may be made of glass, or plastic colorless polyimide or the like with flexible properties.

In an exemplary embodiment, the color film structure layer 105 may include a black matrix (BM) and color filters (CFs). The color filters are provided in red sub-pixels, green sub-pixels and blue sub-pixels respectively, and filter white light emitted by the light emitting devices into red (R) light, green (G) light, and blue (B) light. The black matrix may be located between adjacent color filters.

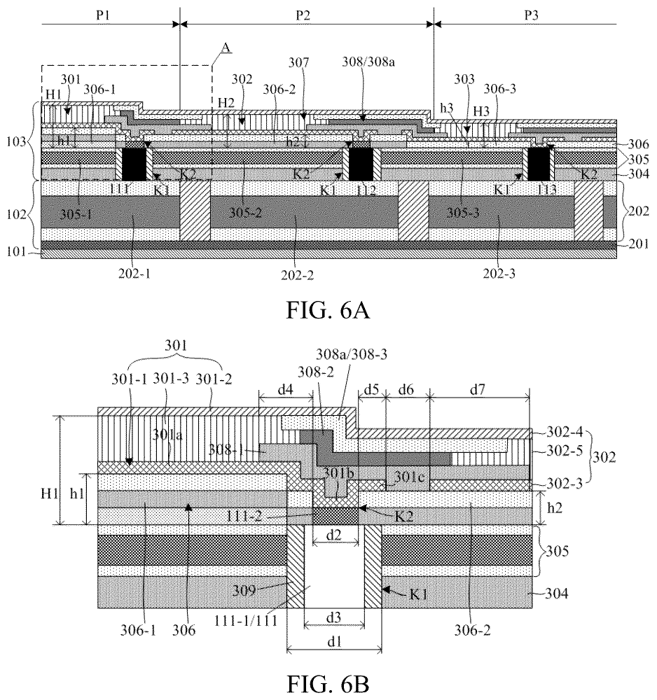

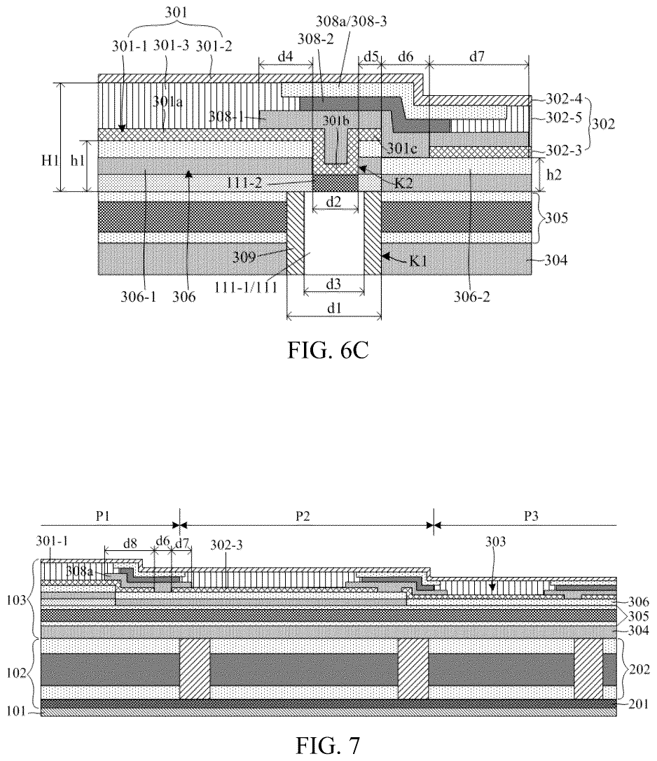

FIG. 6A is a first schematic partial cross-sectional view of a structure of a display substrate according to an embodiment of the present disclosure. As shown in FIG. 6A, only a case in which one pixel unit is illustrated is taken as an example. The display substrate may include a base substrate 101, a drive circuit layer 102 provided on the base substrate 101, and a light emitting structure layer 103 provided on a side of the drive circuit layer 102 away from the base substrate 101. The light emitting structure layer 103 may include multiple light emitting devices, and the multiple light emitting devices may at least include a first light emitting device 301, a second light emitting device 302, and a third light emitting device 303. In an embodiment of the present disclosure, the first light emitting device 301, the second light emitting device 302, and the third light emitting device 303 are all configured to emit white light.

As shown in FIG. 6A, the drive circuit layer 102 may include a circuit structure layer 201 and a connection layer 202. The circuit structure layer 201 may include multiple pixel drive circuits, the pixel drive circuits may include multiple transistors and a storage capacitor, and the transistors may include a gate electrode, a first pole, and a second pole. The connection layer 202 may include multiple connection electrodes, and the multiple connection electrodes may at least include a first connection electrode 202-1, a second connection electrode 202-2, and a third connection electrode 202-3. The first connection electrode 202-1 is configured to connect the first light emitting device 301 and a pixel drive circuit electrically connected to the first light emitting device 301. The second connection electrode 202-2 is configured to connect the second light emitting device 302 and a pixel drive circuit electrically connected to the second light emitting device 302. The third connection electrode 202-3 is configured to connect the third light emitting device 303 and a pixel drive circuit electrically connected to the third light emitting device 303.

In an exemplary embodiment, the connection layer 202 may be made of metallic material(s), such as any one or more of molybdenum (Mo), aluminum (Al), copper (Cu), and titanium (Ti). Alternatively, the connection layer 202 may be made of an alloy material of metal materials, such as molybdenum (Mo), aluminum (Al), copper (Cu), and titanium (Ti), for example, an aluminum-neodymium alloy (AlNd), a molybdenum-niobium alloy (MoNb), or a molybdenum-nickel-titanium alloy (MoNiTi). The connection layer 202 may be a monolayer structure or a multilayer composite structure, such as Ti/Al/Ti or Mo/Nb/Cu or MoNiTi/Cu or MoNb/Cu/MoNiTi or MoNiTi/Cu/MoNiTi or the like.

In an exemplary embodiment, as shown in FIG. 6A, the light emitting structure layer 103 may further include an insulation layer 304, a reflection layer 305 located on a side of the insulation layer 304 away from the base substrate 101, and a micro-cavity adjustment layer 306 located on a side of the reflection layer 305 away from the base substrate 101. The multiple light emitting devices are located on a side of the micro-cavity adjustment layer 306 away from the base substrate 101.

As shown in FIG. 6A, the reflection layer 305 may have multiple first vias K1, and a first via K1 penetrates the reflection layer 305 and the insulation layer 304 in a thickness direction of the display substrate, and exposes a portion of a surface of the connection electrode away from the base substrate 101. The first via K1 is configured such that the light emitting device is connected to the connection electrode via the first via. For example, the first via K1 may be a rectangular hole, a circular hole, a hexagonal hole, or the like.

As shown in FIG. 6A, the micro-cavity adjustment layer 306 may have multiple second vias K2, and a second via K2 penetrates the micro-cavity adjustment layer 306 in the thickness direction of the display substrate. Multiple second vias K2 and multiple first vias K1 are provided in groups in one-to-one correspondence, and a second via K2 is communicated with a first via K1. An orthographic projection of the second via K2 on a plane where the display substrate is located is located within an orthographic projection of the first via K1 on the plane where the display substrate is located, and an area of the orthographic projection of the second via K2 on the plane where the display substrate is located is less than an area of the orthographic projection of the first via K1 on the plane where the display substrate is located. For example, the second via K2 may be a rectangular hole, a circular hole, a hexagonal hole, or the like.

In an exemplary embodiment, as shown in FIG. 6A, the reflection layer 305 may include multiple reflection electrodes, and the multiple reflection electrodes may at least include a first reflection electrode 305-1, a second reflection electrode 305-2, and a third reflection electrode 305-3. The first reflection electrode 305-1 is used to cause light emitted from the first light emitting device 301 to produce a micro-resonant cavity effect, the second reflection electrode 305-2 is used to cause light emitted from the second light emitting device 302 to produce a micro-resonant cavity effect, and the third reflection electrode 305-3 is used to cause light emitted from the third light emitting device 303 to produce a micro-resonant cavity effect.

In an exemplary embodiment, the reflection layer 305 may be made of metallic material(s), such as any one or more of molybdenum (Mo), aluminum (Al), copper (Cu), and titanium (Ti). Alternatively, the reflection layer 305 may be made of an alloy material of metal materials, such as molybdenum (Mo), aluminum (Al), copper (Cu), and titanium (Ti), for example, an aluminum-neodymium alloy (AlNd), a molybdenum-niobium alloy (MoNb), or a molybdenum-nickel-titanium alloy (MoNiTi). The reflection layer 305 may be a monolayer structure or a multilayer composite structure, such as Ti/Al/Ti or Mo/Nb/Cu or MoNiTi/Cu or MoNb/Cu/MoNiTi or MoNiTi/Cu/MoNiTi or the like.

In an exemplary embodiment, as shown in FIG. 6A, the display substrate may further include multiple conductive structures, at least portions of the multiple conductive structures may be located within the first via K1, and a conductive structure is configured to connect the light emitting device of the sub-pixel where the conductive structure is located and the connection electrode. The multiple conductive structures may include a first conductive structure 111, a second conductive structure 112, and a third conductive structure 113. As shown in FIG. 6A, the first light emitting device 301 may be connected to the first connection electrode 202-1 via the first conductive structure 111, the second light emitting device 302 may be connected to the second connection electrode 202-2 via the second conductive structure 112, and the third light emitting device 303 may be connected to the third connection electrode 202-3 via the third conductive structure 113. By way of example, a portion of the first conductive structure 111 may be located within the first via K1, and the rest of the first conductive structure 111 may be located within the second via K2. By way of example, a portion of the second conductive structure 112 may be located within the first via K1, and the rest of the second conductive structure 112 may be located within the second via K2. Alternatively, all of the second conductive structure 112 may be located within the first via K1. By way of example, all of the third conductive structure 113 may be located within the first via K1.

In an exemplary embodiment, as shown in FIG. 6A, the micro-cavity adjustment layer 306 may include multiple adjustment parts, the multiple adjustment parts may at least include a first adjustment part 306-1, a second adjustment part 306-2, and a third adjustment part 306-3, and thicknesses of the first adjustment part 306-1, the second adjustment part 306-2, and the third adjustment part 306-3 are different. In an embodiment of the present disclosure, the thickness direction is perpendicular to the plane where the display substrate is located. As shown in FIG. 6A, the first adjustment part 306-1 has a first thickness h1, the second adjustment part 306-2 has a second thickness h2, and the third adjustment part 306-3 has a third thickness h3, and h1 is greater than h2, and h2 is greater than h3. In an embodiment of the present disclosure, by providing adjustment parts with different thicknesses, the micro-cavity structures respectively formed by the three sub-pixels may have different cavity lengths of micro-cavities. In an embodiment of the present disclosure, a cavity length of a micro-cavity refers to a distance of optical resonant cavity between the cathode and the reflection layer of the sub-pixel.

As shown in FIG. 6A, the first sub-pixel P1 has a first micro-cavity cavity length H1, the second sub-pixel P2 has a second micro-cavity cavity length H2, and the third sub-pixel P3 has a third micro-cavity cavity length H3, and H1 is greater than H2, and H2 is greater than H3. The display substrate provided by an embodiment of the present disclosure may utilize a strong micro-cavity effect, so that among the light emitted by the organic emitting layer of each sub-pixel, light near a wavelength corresponding to a resonant wavelength of the micro-cavity cavity length is enhanced and a spectrum is widened, while light of other wavelengths not corresponding to the resonant wavelength is weakened and a spectrum is narrowed. In this way, the light emitting structure layer located at the first sub-pixel P1 mainly emits light of the first color, the light emitting structure layer located at the second sub-pixel P2 mainly emits light of the second color, and the light emitting structure layer located at the third sub-pixel P3 mainly emits light of the third color. Since the color of the light emitted by the light emitting structure layer located at each sub-pixel is the same as the color of the light allowed to be transmitted by the color filter of the sub-pixel, the light energy loss caused by the light passing through the color filter may be minimized, so that the light emitting efficiency of the display substrate may be improved, and the display effect of the display product may be improved.

In an exemplary embodiment, the thickness of the first adjustment part 306-1 may range from 1300 angstroms to 1700 angstroms, and the thickness of the second adjustment part 306-2 may range from 1200 angstroms to 1600 angstroms. The thickness of the third adjustment part 306-3 may range from 200 angstroms to 600 angstroms. By limiting the thickness ranges of the first adjustment part, the second adjustment part, and the third adjustment part, it is possible to avoid a large thickness step difference in the micro-cavity adjustment layer, to avoid a large slope climbing in the anode layers of the light emitting structure layer, and to improve the reliability of the light emitting device. By limiting the thickness range of the third adjustment part, parasitic capacitance between the third light emitting device and the reflection layer may be avoided, and the light emitting performance of the third light emitting device may be improved.

In an exemplary embodiment, the light emitting structure layer 103 may further include a light emitting composite layer 307 located on a side of the micro-cavity adjustment layer 306 away from the base substrate 101, and a pixel definition layer 308. The light emitting composite layer 307 may include multiple light emitting devices, the pixel definition layer 308 have multiple opening areas, and the pixel definition layer 308 may include multiple partition parts 308a. A partition part 308a is provided around an opening area, and light emitted by the light emitting devices may be emitted through the corresponding opening areas. The detailed structure of the partition part 308a may be referred in the description of FIG. 6B. The light emitting composite layer 307 may include an anode layer, an organic emitting layer, and a cathode layer disposed sequentially in a direction away from the base substrate 101. The organic emitting layer may emit light under the drive of the anode layer and the cathode layer.

In an exemplary embodiment, a material of the anode layer may be a transparent conductive oxide material, and the transparent conductive oxide material may include indium tin oxide (ITO) or indium zinc oxide (IZO). By way of example, the anode layer may be a monolayer structure or a multilayer composite structure, such as ITO/Al/ITO or the like. For example, a thickness of the anode layer may range from 120 angstroms to 200 angstroms.

FIG. 6B is a partially enlarged schematic view at identification A in FIG. 6A. As shown in FIG. 6B, the first conductive structure 111 may include a first section 111-1 and a second section 111-2 which are connected, and the first section 111-1 is not colored in FIG. 6B for easy identification. The first section 111-1 is located within the first via K1, and the second section 111-2 is located within the second via K2. An orthographic projection of the second section 111-2 on a plane where the display substrate is located is located within an orthographic projection of the first section 111-1 on the plane where the display substrate is located, and an area of the orthographic projection of the second section 111-2 on the plane where the display substrate is located is less than an area of the orthographic projection of the first section 111-1 on the plane where the display substrate is located. The first conductive structure 111 is designed as a combination of the first section 111-1 and the second section 111-2, and an orthographic projection relationship between the first section 111-1 and the second section 111-2 is defined. In a process of preparing the display substrate, a via for accommodating the first conductive structure 111 may be made by using a yellow light overlay lithography process, and the via may be guaranteed to have a high dimensional accuracy. By way of example, the first section 111-1 may be cylindrical and the second section 111-2 may be cylindrical.

In an exemplary embodiment, as shown in FIG. 6B, the first light emitting device 301 may include a first electrode 301-1, a first organic emitting layer 301-3, and a second electrode 301-2, the first electrode 301-1 is located in the anode layer, the first organic emitting layer 301-3 is located in the organic emitting layer, and the second electrode 301-2 is located in the cathode layer. The first electrode 301-1 may be connected to the second pole of the transistor through the first connection electrode, the first organic emitting layer 301-3 may be connected to the first electrode 301-1, the second electrode 301-2 may be connected to the first organic emitting layer 301-3, the second electrode 301-2 may be connected to the second power supply line, and the first organic emitting layer 301-3 may be driven by the first electrode 301-1 and the second electrode 301-2 to emit light. In an embodiment of the present disclosure, the second power supply line is configured to continuously provide a low level signal to the light emitting device. The first electrode 301-1 may be an anode of the first light emitting device 301 and the second electrode 301-2 may be a cathode of the first light emitting device 301.

In an exemplary embodiment, as shown in FIG. 6B, at least a portion of the first electrodes 301-1 may be located on a side of the micro-cavity adjustment layer 306 away from the reflection layer 305, and, by way of example, all of the first electrodes 301-1 may be located on a side of the micro-cavity adjustment layer 306 away from the reflection layer 305. Alternatively, a portion of the first electrode 301-1 may be located on a side of the micro-cavity adjustment layer 306 away from the reflection layer 305, and the rest of the first electrode 301-1 may be located within the second via K2, and a size of the rest of the first electrode 301-1 in the thickness direction of the display substrate does not exceed 50% of a aperture depth of the second via K2. In an embodiment of the present disclosure, by defining a depth (a size in the thickness direction of the display substrate) at which the first electrode 301-1 is located in the second via K2, the impedance of the first electrode due to ramping may be reduced, the power consumption of the light emitting device may be reduced, and the overall performance of the display product may be improved.

In an exemplary embodiment, as shown in FIG. 6B, the first electrode 301-1 may include a first portion 301a, a second portion 301b, and a third portion 301c that are connected. The first portion 301a and the third portion 301c may both be located on a side of the micro-cavity adjustment layer 306 away from the reflection layer 305, the second portion 301b may be located within the second via K2, and an edge of an orthographic projection of the second portion 301b on the plane where the display substrate is located coincides with an edge of an orthographic projection of the second via K2 on the plane where the display substrate is located. As shown in FIG. 6B, in a radial direction of the second via K2, a thickness range of the second portion 301b may be greater than or equal to 30% of a thickness of the first portion 301a, and less than or equal to the thickness of the first portion 301a. For example, the thickness of the first portion 301a may be 200 angstroms, the thickness of the second portion 301b may be 60 angstroms, or the thickness of the first portion 301a may be 100 angstroms. In an embodiment of the present disclosure, by defining the thickness difference between the first portion 301a and the second portion 301b, the overall impedance of the first electrode 301-1 in the region of the second via K2 may be reduced, and the light emitting efficiency of the light emitting device may be improved.

As shown in FIG. 6B, the second via K2 has a first end and a second end provided opposite to each other, and the first end is further away from the reflection layer 305 compared to the second end, and an aperture of the first end is the same as an aperture of the second end. The second via K2 may be prepared by a semi-back etching process, which may save the step of yellow light overlay lithography. The yellow light overlay lithography requires an upper layer aperture to be smaller than a lower layer aperture to ensure an accuracy of overlay lithography. Adding one step of yellow light overlay lithography process will cause the aperture of the first via K1 to be increased by 0.04 micron to 0.1 micron. Therefore, the aperture of the first end of the second via K2 is the same as the aperture of the second end, so that the aperture of the first via K1 may be reduced.

In an exemplary embodiment, as shown in FIG. 6B, the second light emitting device 302 may include a third electrode 302-3, a second organic emitting layer 302-5, and a fourth electrode 302-4, the third electrode 302-3 is located in the anode layer, the second organic emitting layer 302-5 is located in the organic emitting layer, and the fourth electrode 302-4 is located in the cathode layer. The third electrode 302-3 may be connected to the second pole of the transistor through the second connection electrode, the second organic emitting layer 302-5 may be connected to the third electrode 302-3, the fourth electrode 302-4 may be connected to the second organic emitting layer 302-5, the fourth electrode 302-4 may be connected to the second power supply line, and the second organic emitting layer 302-5 may be driven by the third electrode 302-3 and the fourth electrode 302-4 to emit light. The third electrode 302-3 may be an anode of the second light emitting device 302 and the fourth electrode 302-4 may be a cathode of the second light emitting device 302.

In an exemplary embodiment, the third light emitting device 303 may include a fifth electrode, a third organic emitting layer, and a sixth electrode, the fifth electrode is located in the anode layer, the third organic emitting layer is located in the organic emitting layer, and the sixth electrode is located in the cathode layer. The fifth electrode may be connected to the second pole of the transistor through the third connection electrode, the third organic emitting layer is connected to the fifth electrode, the sixth electrode is connected to the third organic emitting layer, the sixth electrode may be connected to the second power supply line, and the third organic emitting layer is driven by the fifth electrode and the sixth electrode to emit light. The fifth electrode may be an anode of the third light emitting device 303 and the sixth electrode may be a cathode of the third light emitting device 303. The cathode of the first light emitting device 301, the cathode of the second light emitting device 302, and the cathode of the third light emitting device 303 may be interconnected to form an integral structure. In an embodiment of the present disclosure, the cooperation relationship between the third electrode and the second via and the cooperation relationship between the fifth electrode and the second via may be referred to the cooperation relationship between the first electrode and the second via, which will not be further described herein. In an embodiment of the present disclosure, the third conductive structure and the second conductive structure may be designed with reference to the first conductive structure, which will not be further described herein.

In an exemplary embodiment, as shown in FIG. 6B, the pixel definition layer may include multiple partition parts 308a. The structures of the multiple partition parts 308a may be the same or different, as shown in FIG. 6B, taking one of the partition part structures as an example. A partition part 308a may include multiple film layers, the multiple film layers may include a first sub-layer 308-1, a second sub-layer 308-2, and a third sub-layer 308-3 provided sequentially in a direction away from the reflection layer 305. An orthographic projection of the second sub-layer 308-2 on the plane where the display substrate is located may be located within an orthographic projection of the first sub-layer 308-1 on the plane where the display substrate is located, and an area of the orthographic projection of the second sub-layer 308-2 on the plane where the display substrate is located is less than an area of the orthographic projection of the first sub-layer 308-1 on the plane where the display substrate is located. An orthographic projection of the third sub-layer 308-3 on the plane where the display substrate is located includes the orthographic projection of the second sub-layer 308-2 on the plane where the display substrate is located, and an area of the orthographic projection of the third sub-layer 308-3 on the plane where the display substrate is located is greater than the area of the orthographic projection of the second sub-layer 308-2 on the plane where the display substrate is located. The orthographic projection of the third sub-layer 308-3 on the plane where the display substrate is located is located within the orthographic projection of the first sub-layer 308-1 on the plane where the display substrate is located. As shown in FIG. 6B, the multiple film layers of the partition part 308a form an undercut structure, which may reduce a size of the partition part, increase an aperture ratio of the display substrate, and facilitate the disconnection of the organic emitting layer at the partition part, thereby avoiding crosstalk of light between adjacent sub-pixels and improving the display quality of the display product. Moreover, the partition part with the undercut structure may avoid a problem of cathode puncture or breakage caused by a deformation of an edge of the partition part.

In an exemplary embodiment, as shown in FIG. 6B, a material of the first sub-layer 308-1 and the third sub-layer 308-3 may include a silicon oxide (SiOₓ). For example, the silicon oxide (SiOₓ) may be silicon oxide. A material of the second sub-layer 308-2 may include a silicon nitride (SiNₓ). For example, the silicon nitride (SiNₓ) may be silicon nitride. In an embodiment of the present disclosure, a material of the second sub-layer 308-2 is designed to be different from a material of the first sub-layer 308-1 and a material of the third sub-layer 308-3, so that the partition part facilitates the formation of the undercut structure.

In an exemplary embodiment, as shown in FIG. 6B, the reflection layer 305 may have multiple first vias K1, a maximum aperture of the first via K1 is d1, and a range of d1 may be from 0.5 micron to 0.7 micron. For example, the first via K1 may be a circular hole, a rectangular hole, an oval hole, or the like. The micro-cavity adjustment layer 306 may have multiple second vias K2, a maximum aperture of the second via K2 is d2, and d2 is less than d1, and a range of d2 may be from 0.3 micron to 0.5 micron. A central axis of the second via K2 along its length direction is collinear or parallel to a central axis of the first via K1 along its length direction.

In an exemplary embodiment, as shown in FIG. 6B, the light emitting structure layer 103 may also include an isolation layer 309, the isolation layer 309 is located within the first via K1, and the isolation layer 309 is provided around the first section 111-1. An orthographic projection of the isolation layer 309 on the plane where the display substrate is located may be annular, and an annular width of the isolation layer 309 may range from 0.2 micron to 0.3 micron, which may ensure that no induced capacitance is generated in the first via region, and may ensure that the sub-pixel has a large opening area.

In an exemplary embodiment, the first adjustment part 306-1 has a first thickness h1, the second adjustment part 306-2 has a second thickness h2, the third adjustment part 306-3 has a third thickness h3, and h1 is greater than h2, and h2 is greater than h3, and the third thickness h3 is greater than a maximum value of a ring width of the isolation layer 309. This design may reduce a parasitic capacitance between the conductive structure and the reflection layer, and may improve the display quality of the display apparatus.

In an exemplary embodiment, a material of the isolation layer 309 may be an inorganic material or an organic material, for example, the inorganic material may be any one or more of silicon oxide nitride (SiOₓN_{y}), silicon nitride (SiNₓ), silicon oxide (SiOₓ), and the like. For example, the organic material(s) may be any one or several of epoxy resins, phenolic resins, urea-formaldehyde resins, melamine-formaldehyde resins, furan resins, silicone resins, polyester resins, polyamide resins, acrylic resins, polyurethane resins, vinyl resins, hydrocarbon resins, polyether resins, and the like.

In an exemplary embodiment, as shown in FIG. 6B, an orthographic projection of the first section 111-1 on the plane where the display substrate is located may be circular, and a first diameter of the first section 111-1 is d3, then a difference between d3 and d2 may be greater than or equal to 0.04 micron, and less than or equal to 0.1 micron, and d3 is greater than d2.

In an exemplary embodiment, as shown in FIG. 6B, there is a first overlapping region between an orthographic projection of the first portion 301a of the first electrode 301-1 on the plane where the display substrate is located and an orthographic projection of the partition part 308a on the plane where the display substrate is located. A length of the first overlapping region is labeled as d4 and a range of d4 may be from 0.25 micron to 0.45 micron. In an embodiment of the present disclosure, by defining a length d4 of the first overlapping region, the light emitting efficiency of the first light emitting device may be improved, and an edge of the first electrode 301-1 may be protected by using the partition part 308a, water and oxygen may be prevented from intruding into the first light emitting device through an edge of the first electrode 301-1, and a service reliability of the first light emitting device may be improved.

In an exemplary embodiment, as shown in FIG. 6B, there is a second overlapping region between an orthographic projection of the third portion 301c of the first electrode 301-1 on the plane where the display substrate is located and an orthographic projection of the partition part 308a on the plane where the display substrate is located. A length of the second overlapping region is labeled as d5 and a range of d5 may be from 0.04 micron to 0.1 micron. In an embodiment of the present disclosure, by defining a length d5 of the second overlapping region, it is possible to prevent water and oxygen from intruding into the first conductive structure through an edge of the third portion 301c, and it is possible to improve a reliability of an electrical connection of the first conductive structure.

In an exemplary embodiment, as shown in FIG. 6B, there is a gap d6 between an orthographic projection of the first electrode 301-1 on the plane where the display substrate is located and an orthographic projection of the third electrode 302-3 on the plane where the display substrate is located, and a range of d6 may be from 0.2 micron to 0.5 micron. In an embodiment of the present disclosure, by defining the gap d6 between the first electrode 301-1 and the third electrode 302-3, an electric connection between the first light emitting device and the second light emitting device may be avoided, a separate control of the first light emitting device and the second light emitting device may be realized, and a control accuracy of the display product may be improved.

In an exemplary embodiment, as shown in FIG. 6B, there is a gap d6 between an orthographic projection of the first electrode 301-1 on the plane where the display substrate is located and an orthographic projection of the third electrode 302-3 on the plane where the display substrate is located, and the gap d6 may be greater than a difference between the aperture of the first via K1 and the aperture of the second via K2. By reserving a sufficient gap d6, a process accuracy requirement may be lowered, and a manufacturing cost of the display apparatus may be reduced. Generally, affected by a supply relationship of each component of the display substrate, the light emitting device and the conductive structure are manufactured by different manufacturers. Since the manufacturing precision of different manufacturers varies, a precision of the light emitting device is usually lower than a precision of the conductive structure. Therefore, by reserving a sufficient gap d6, process feasibility may be guaranteed, and a manufacturing cost of the display apparatus may be reduced. In an exemplary embodiment, an edge of an orthographic projection of the third portion 301c on the plane where the display substrate is located and close to the second light emitting device may be located within a range of an orthographic projection of the isolation layer 309 on the plane where the display substrate is located, the gap d6 may be increased, and the signal crosstalk between two adjacent sub-pixels may be reduced.

In an exemplary embodiment, as shown in FIG. 6B, there is a third overlapping region between an orthographic projection of the third electrode 302-3 on the plane where the display substrate is located and an orthographic projection of the partition part 308a on the plane where the display substrate is located. A length of the third overlapping region is labeled as d7, and a range of d7 may be from 0.6 micron to 1.0 micron. In an embodiment of the present disclosure, by defining a length d7 of the third overlapping region, the light emitting efficiency of the second light emitting device may be improved, and an edge of the third electrode 302-3 may be protected by using the partition part 308a, water and oxygen may be prevented from intruding into the second light emitting device through an edge of the third electrode 302-3, and a service reliability of the second light emitting device may be improved.

In an exemplary embodiment, as shown in FIG. 6B, an orthographic projection of the partition part 308a on the plane where the display substrate is located may include an orthographic projection of the first via K1 on the plane where the display substrate is located. For example, the orthographic projection of the partition part 308a on the plane where the display substrate is located is greater than the orthographic projection of the first via K1 on the plane where the display substrate is located. Therefore, it is possible to avoid an occupation of an area of the light emitting region of the light emitting device by providing the first via K1. For a single light emitting device, a design of a full-surface reflection layer may be realized, the light output efficiency of a single sub-pixel can be improved, and an overall aperture ratio of the display substrate may be improved. By adopting the display substrate provided in an embodiment of the present disclosure, the aperture ratio of the display substrate may be greater than 65%.

FIG. 6C is a schematic partial cross-sectional view of a structure of a display substrate according to another embodiment of the present disclosure. As shown in FIG. 6C, an orthographic projection of a third portion 301c of a first electrode 301-1 on the plane where the display substrate is located may be located within an orthographic projection of a first adjustment part 306-1 on the plane where the display substrate is located, and an orthographic projection of the third electrode 302-3 on the plane where the display substrate is located may be located within an orthographic projection of a second adjustment part 306-2 on the plane where the display substrate is located. On the basis that there is the gap d6 between the orthographic projection of the first electrode 301-1 on the plane where the display substrate is located and the orthographic projection of the third electrode 302-3 on the plane where the display substrate is located, since a thickness of the first adjustment part 306-1 is greater than a thickness of the second adjustment part 306-2, there is a gap between the third portion 301c and the third electrode 302-3 in the thickness direction of the display substrate, so that the risk of crosstalk between adjacent sub-pixels may be further reduced.

FIG. 7 is a second schematic partial cross-sectional view of a structure of a display substrate according to an embodiment of the present disclosure. A cutting position of the schematic cross-sectional view shown in FIG. 7 does not pass through the first via and the second via. In contrast, a cutting position of the schematic cross-sectional view shown in FIG. 6A passes through the first via and the second via. As shown in FIG. 7, there is an overlapping region between an orthographic projection of the first electrode 301-1 on the plane where the display substrate is located and an orthographic projection of the partition part 308a on the plane where the display substrate is located. A length of the overlapping region is labeled as d8, and a range of d8 may be from 0.6 micron to 1.0 micron. In an embodiment of the present disclosure, by defining a length d8 of the overlapping region, it is possible to prevent water and oxygen from intruding into the first light emitting device through an edge of the first electrode 301-1, and a service reliability of the first light emitting device may be improved. For example, d8 may be equal to a sum of d4, d2, and d5.

A structure of the display substrate will be described below through an example of a manufacturing process of the display substrate. A “patterning process” mentioned in an embodiment of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition process may be any one or more of sputtering, evaporation deposition, and chemical vapor deposition, coating process may be any one or more of spray coating, spin coating, and inkjet printing, and etching process may be any one or more of dry etching and wet etching, the present disclosure is not limited thereto. A “thin film” refers to a layer of thin film made of a material on a base substrate by using deposition, coating, or another process. If the “thin film” does not need to be processed through a patterning process in the entire manufacturing process, the “thin film” may also be called a “layer”. If the “thin film” needs to be processed through a patterning process in the entire manufacturing process, the “thin film” is called a “thin film” before the patterning process is performed and is called a “layer” after the patterning process is performed. At least one “pattern” is contained in the “layer” which has been processed through the patterning process. In the present disclosure, “A and B are of a same layer structure” mentioned in the present disclosure means that A and B are formed through a same one-time patterning process.

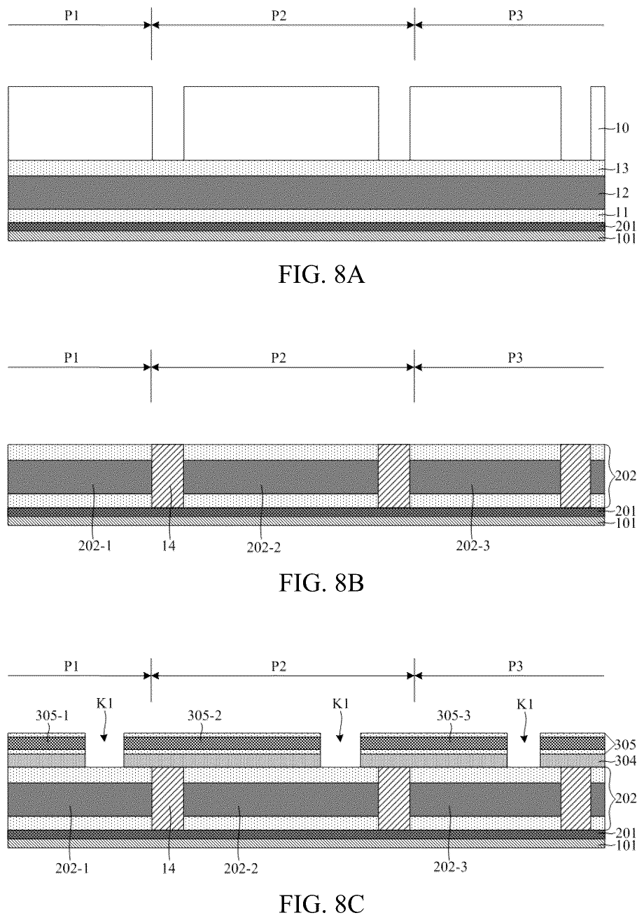

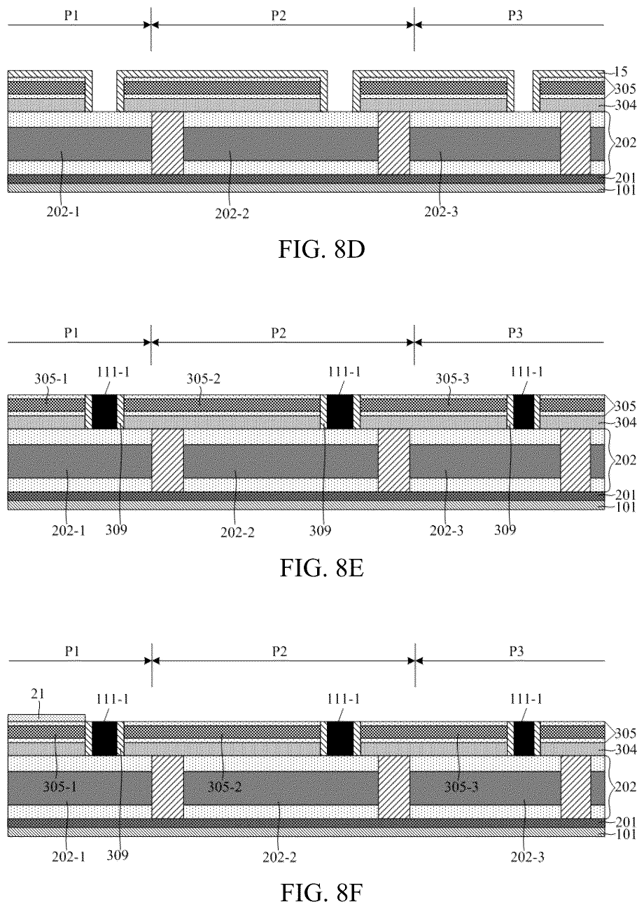

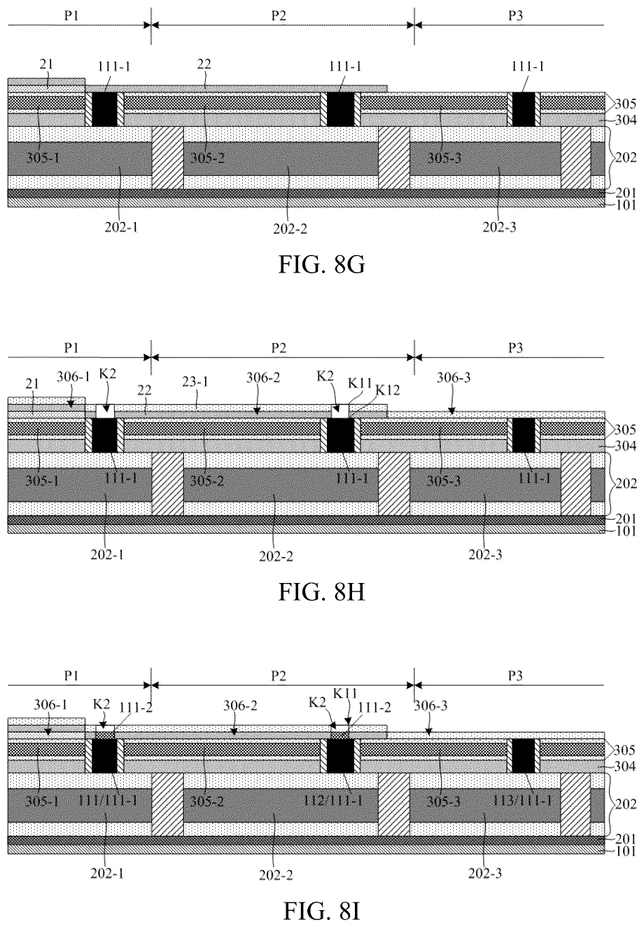

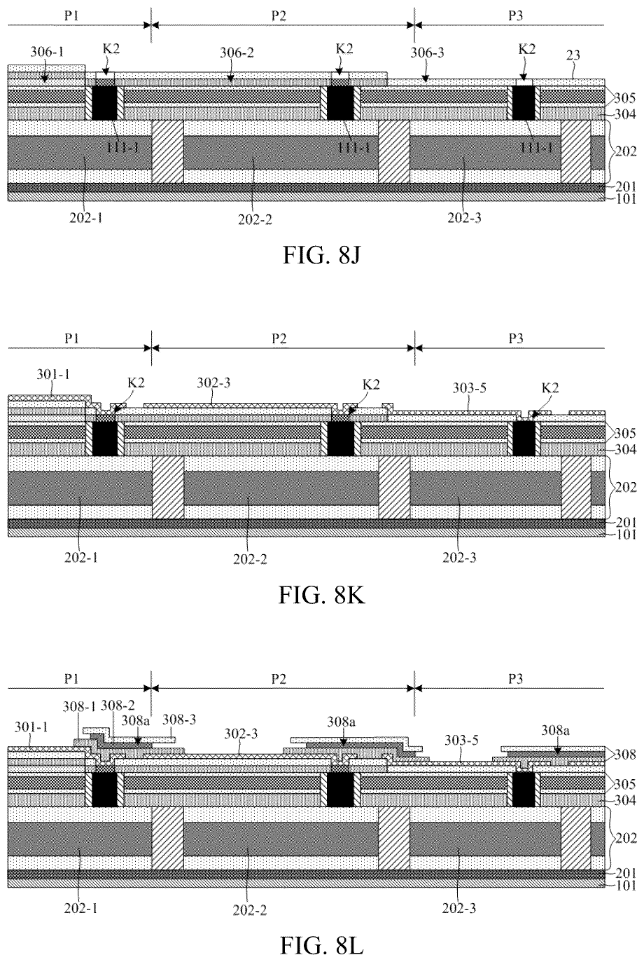

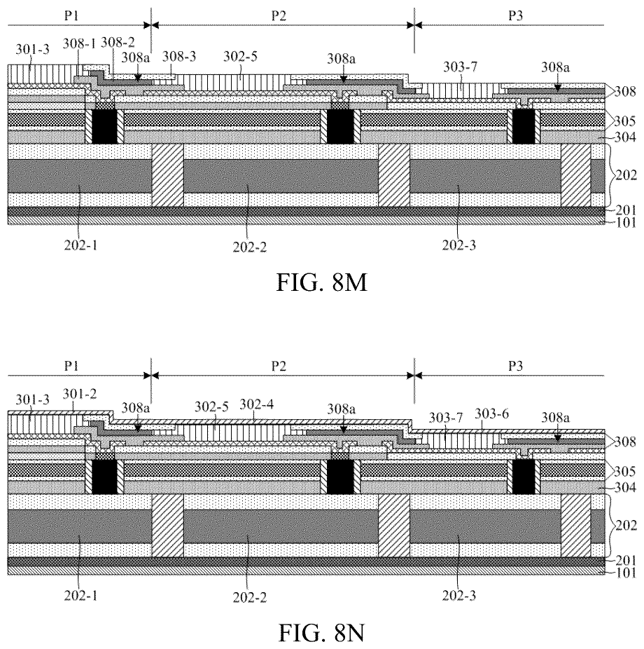

The manufacturing process of the display substrate may include the following steps, taking one pixel unit as an example, and as shown in FIGS. 8A to 8N.
(11) Forming a photoresist pattern. Forming a photoresist pattern may include forming a circuit structure layer 201 on a side of a base substrate 101, sequentially depositing a first conductive thin film 11, a second conductive thin film 12, and a third conductive thin film 13 on a side of the circuit structure layer 201 away from the base substrate 101, forming a photoresist thin film on a side of the third conductive thin film 13 away from the base substrate 101, and patterning the photoresist thin film by a patterning process to form a photoresist pattern 10 on a side of the third conductive thin film 13 away from the base substrate 101, as shown in FIG. 8A.

The circuit structure layer 201 may include multiple pixel drive circuits, a pixel drive circuit may include multiple transistors and a storage capacitor, and a transistor may include a gate electrode, a first pole, and a second pole. In one example, a semiconductor layer of the transistor may adopt a Complementary Metal Oxide Semiconductor (CMOS) layer.
(12) Forming a pattern of a metal wiring layer. Forming the pattern of the metal wiring layer may include applying a patterning process to the base substrate 101 on which the aforementioned pattern is formed such that the first conductive thin film 11, the second conductive thin film 12, and the third conductive thin film 13 form a connection layer 202. The connection layer 202 may include multiple connection electrodes, and the multiple connection electrodes may at least include a first connection electrode 202-1, a second connection electrode 202-2, and a third connection electrode 202-3, as shown in FIG. 8B. The first connection electrode 202-1 is configured to connect a first light emitting device to be formed subsequently and a pixel drive circuit electrically connected to the first light emitting device. The second connection electrode 202-2 is configured to connect a second light emitting device to be formed subsequently and a pixel drive circuit electrically connected to the second light emitting device. The third connection electrode 202-3 is configured to connect a third light emitting device to be formed subsequently and a pixel drive circuit electrically connected to the third light emitting device.

Forming the pattern of the metal wiring layer may also include depositing a fourth conductive thin film on a side of the base substrate 101 on which the aforementioned patterns are formed to form a metal wiring layer 14, as shown in FIG. 8B. There is a gap between two adjacent connection electrodes, and the metal wiring layer 14 may be located within the gap, and a surface of the metal wiring layer 14 away from the base substrate 101 may be flush with a surface of the connection layer 202 away from the base substrate 101.
(13) Forming a pattern of a reflection layer. Forming the pattern of the reflection layer may include sequentially depositing a first insulation thin film, a fifth conductive thin film, a sixth conductive thin film, and a seventh conductive thin film on a side of the base substrate 101 on which the aforementioned patterns are formed, and patterning the seventh conductive thin film by a patterning process so that the fifth conductive thin film, the sixth conductive thin film, and the seventh conductive thin film form the pattern of the reflection layer, and the first insulation thin film forms an pattern of an insulation layer, as shown in FIG. 8C.

As shown in FIG. 8C, the reflection layer 305 may have multiple first vias K1, a first via K1 penetrates the reflection layer 305 and the insulation layer 304 in the thickness direction of the display substrate, and exposes a portion of a surface of the connection electrode away from the base substrate 101. The first via K1 is configured such that the light emitting device to be formed subsequently is connected to the corresponding connection electrode via the first via.

As shown in FIG. 8C, the reflection layer 305 may include multiple reflection electrodes, and the multiple reflection electrodes may at least include a first reflection electrode 305-1, a second reflection electrode 305-2, and a third reflection electrode 305-3. The first reflection electrode 305-1 is used to cause light emitted by the first light emitting device to be formed subsequently to produce a micro-resonant cavity effect, the second reflection electrode 305-2 is used to cause light emitted by the second light emitting device to be formed subsequently to produce a micro-resonant cavity effect, and the third reflection electrode 305-3 is used to cause light emitted by the third light emitting device to be formed subsequently to produce a micro-resonant cavity effect.
(14) Forming a pattern of an isolation layer. Forming the pattern of the isolation layer may include depositing a second insulation thin film 15 on a side of the base substrate 101 on which the aforementioned patterns are formed, as shown in FIG. 8D. The second insulation thin film 15 covers a side wall of the first via K1, and the second insulation thin film 15 does not fill the first via K1. The second insulation thin film 15 exposes a portion of a surface of the connection electrode away from the base substrate 101. The second insulation thin film 15 may be used to isolate a conductive structure to be formed subsequently from the reflection layer 305.

Forming the pattern of the isolation layer may also include performing a patterning process on the aforementioned second insulation thin film 15 to form an isolation layer 309, as shown in FIG. 8E. A surface of the isolation layer 309 away from the base substrate 101 is substantially flush with a surface of the reflection layer 305 away from the base substrate 101.
(15) Forming an initial pattern of a conductive structure. Forming the initial pattern of the conductive structure may include depositing an eighth conductive thin film on a side of the base substrate 101 on which the aforementioned patterns are formed, and patterning the eighth conductive thin film by a patterning process to form the initial pattern of the conductive structure located within the first via K1, as shown in FIG. 8E. By way of example, a material of the eighth conductive thin film may be tungsten.

As shown in FIG. 8E, the initial pattern of the conductive structure may include multiple first sections 111-1. A first section 111-1 is located within the first via K1, and a surface of the first section 111-1 away from the base substrate 101 may be substantially flush with a surface of the reflection layer 305 away from the base substrate 101, or the surface of the first section 111-1 away from the base substrate 101 may be closer to the base substrate 101 than the surface of the reflection layer 305 away from the base substrate 101. With this design, a light emitting device corresponding to a sub-pixel with a smallest micro-cavity cavity length may be directly lapped with a surface of the first section 111-1 away from the base substrate 101, thereby saving process steps and reducing the manufacturing cost. In a preparation method of an embodiment of the present disclosure, a case in which the partial structures of the first conductive structure, the second conductive structure, and the third conductive structure located within the first via K1 are the same is taken as an example.
(16) Forming a pattern of a first adjustment layer. Forming the pattern of the first adjustment layer may include depositing a third insulation thin film on a side of the base substrate 101 on which the aforementioned patterns are formed, and patterning the third insulation thin film by a patterning process to form the pattern of the first adjustment layer on a side of the reflection layer 305 away from the base substrate 101, as shown in FIG. 8F.

As shown in FIG. 8F, an orthographic projection of the first adjustment layer 21 on the plane where the display substrate is located may at least partially overlap an orthographic projection of the first reflection electrode 305-1 on the plane where the display substrate is located. For example, the orthographic projection of the first adjustment layer 21 on the plane where the display substrate is located may be located within the orthographic projection of the first reflection electrode 305-1 on the plane where the display substrate is located. The first adjustment layer 21 constitutes a portion of a first adjustment part for making the first sub-pixel P1 have a first micro-cavity cavity length.
(17) Forming a pattern of a second adjustment layer. Forming the pattern of the second adjustment layer may include depositing a fourth insulation thin film on a side of the base substrate 101 on which the aforementioned patterns are formed, and patterning the fourth insulation thin film by a patterning process to form the pattern of the second adjustment layer on a side of the first adjustment layer 21 away from the base substrate 101, as shown in FIG. 8G.

As shown in FIG. 8G, an orthographic projection of the second adjustment layer 22 on the plane where the display substrate is located may at least partially overlap an orthographic projection of the first reflection electrode 305-1 on the plane where the display substrate is located, and the orthographic projection of the second adjustment layer 22 on the plane where the display substrate is located may at least partially overlap an orthographic projection of the second reflection electrode 305-2 on the plane where the display substrate is located. For example, the orthographic projection of the second adjustment layer 22 on the plane where the display substrate is located may include the orthographic projection of the first reflection electrode 305-1 on the plane where the display substrate is located and the orthographic projection of the second reflection electrode 305-2 on the plane where the display substrate is located. The portions of the first adjustment layer 21 and the second adjustment layer 22 together constitute a portion of the first adjustment part and the first adjustment part is configured to make the first sub-pixel P1 have the first micro-cavity cavity length. Other portions of the second adjustment layer 22 constitute a portion of a second adjustment part and the second adjustment part is configured to make the second sub-pixel P2 have a second micro-cavity cavity length.
(18) Forming an initial pattern of a third adjustment layer. Forming the initial pattern of the third adjustment layer may include depositing a fifth insulation thin film on a side of the base substrate 101 on which the aforementioned patterns are formed, and patterning the fifth insulation thin film by a patterning process to form the initial pattern of the third adjustment layer 23-1 on a side of the second adjustment layer 22 away from the base substrate 101, as shown in FIG. 8H.

As shown in FIG. 8H, an orthographic projection of the initial pattern of the third adjustment layer 23-1 on the plane where the display substrate is located may include the orthographic projection of the first reflection electrode 305-1 on the plane where the display substrate is located, the orthographic projection of the second reflection electrode 305-2 on the plane where the display substrate is located, and an orthographic projection of the third reflection electrode 305-3 on the plane where the display substrate is located.

As shown in FIG. 8H, the first adjustment part 306-1 includes the first adjustment layer 21, a portion of the second adjustment layer 22, and a portion of the initial pattern of the third adjustment layer 23-1. The second adjustment part 306-2 includes other portions of the second adjustment layer 22 and a portion of the initial pattern of the third adjustment layer 23-1. The third adjustment part 306-3 includes other portions of the initial pattern of the third adjustment layer 23-1. The third adjustment part is configured to make the third sub-pixel P3 to have a third micro-cavity cavity length.

As shown in FIG. 8H, the initial pattern of the third adjustment layer 23-1 may have multiple second vias K2, and both the fourth insulation thin film and the fifth insulation thin film located within a second via K2 are etched away, and a portion of a surface of the first section 111-1 away from the base substrate 101 is exposed. The second via K2 is configured such that a second section to be formed subsequently is located within the second via.

As shown in FIG. 8H, the second via K2 has a first end K11 and a second end K12 provided opposite to each other, and the first end K11 is further away from the reflection layer 305 compared to the second end K12, and an aperture of the first end K11 is the same as an aperture of the second end K12. The second via K2 may be prepared by a semi-back etching process, which may save a step of yellow light overlay lithography. The yellow light overlay lithography requires an upper layer aperture to be smaller than a lower layer aperture to ensure an accuracy of overlay lithography. Adding one step of yellow light overlay lithography process will cause the aperture of the first via K1 to be increased by 0.04 micron to 0.1 micron. Therefore, the aperture of the first end K11 is the same as the aperture of the second end K12, so that the aperture of the first via K1 may be reduced.
(19) Forming a final pattern of a conductive structure. Forming the final pattern of the conductive structure may include depositing a ninth conductive thin film on a side of the base substrate 101 on which the aforementioned patterns are formed, and patterning the ninth conductive thin film by a patterning process to form the final pattern of the conductive structure located within the second via K2, as shown in FIG. 8I.

As shown in FIG. 8I, the final pattern of the conductive structure may include multiple second sections 111-2. A second section 111-2 is located within the second via K2, and a surface of the second section 111-2 away from the reflection layer 305 may be substantially flush with the first end K11 of the second via K2, or a surface of the second section 111-2 away from the reflection layer 305 may be closer to the reflection layer 305 than the first end K11. An orthographic projection of the second section 111-2 on the plane where the display substrate is located may be located within an orthographic projection of the first section 111-1 on the plane where the display substrate is located.

As shown in FIG. 8I, the first section 111-1 and the second section 111-2 located within the first sub-pixel P1 together constitute the first conductive structure 111. The first conductive structure 111 is configured such that the first light emitting device to be formed subsequently is connected to the first connection electrode 202-1 via the first conductive structure 111. The first section 111-1 and the second section 111-2 located within the second sub-pixel P2 together constitute the second conductive structure 112. The second conductive structure 112 is configured such that the second light emitting device to be formed subsequently is connected to the second connection electrode 202-2 via the second conductive structure 112. The first section 111-1 located within the third sub-pixel P3 is the third conductive structure 113 and the third conductive structure 113 is configured such that the third light emitting device to be formed subsequently is connected to the third connection electrode 202-3 via the third conductive structure 113.
(20) Forming a pattern of a third adjustment layer. Forming the pattern of the third adjustment layer may include patterning the fifth insulation thin film located within the third sub-pixel P3 by a patterning process to form the pattern of the third adjustment layer, as shown in FIG. 8J.

As shown in FIG. 8J, the third adjustment layer 23 may have multiple second vias K2, and the fifth insulation thin film located within the second via K2 is etched away and a portion of a surface of the first section 111-1 away from the base substrate 101 is exposed.
(21) Forming a pattern of an anode layer. Forming the pattern of the anode layer may include depositing a tenth conductive thin film on a side of the base substrate 101 on which the aforementioned patterns are formed, and patterning the tenth conductive thin film by a patterning process to form the pattern of the anode layer on a side of the third adjustment layer 23 away from the base substrate 101, as shown in FIG. 8K.

As shown in FIG. 8K, the pattern of the anode layer may include multiple anodes of multiple light emitting devices, and the multiple anodes are provided at intervals to avoid electrical connection crosstalk between different light emitting devices. As shown in FIG. 8K, the pattern of the anode layer may include a first electrode 301-1, a third electrode 302-3, and a fifth electrode 303-5.
(22) Forming a pattern of a pixel definition layer. Forming the pattern of the pixel definition layer may include sequentially depositing a sixth insulation thin film, a seventh insulation thin film, and an eighth insulation thin film on a side of the base substrate 101 on which the aforementioned patterns are formed, and patterning the eighth insulation thin film by a patterning process to form the pattern of the pixel definition layer on a side of the anode layer away from the base substrate 101, as shown in FIG. 8L.

As shown in FIG. 8L, the pixel definition layer 308 may include multiple partition parts 308a. A partition part 308a may include multiple film layers, the multiple film layers may include a first sub-layer 308-1, a second sub-layer 308-2, and a third sub-layer 308-3 provided sequentially in a direction away from the reflection layer 305. An orthographic projection of the second sub-layer 308-2 on the plane where the display substrate is located may be located within an orthographic projection of the first sub-layer 308-1 on the plane where the display substrate is located, and an area of the orthographic projection of the second sub-layer 308-2 on the plane where the display substrate is located is less than an area of the orthographic projection of the first sub-layer 308-1 on the plane where the display substrate is located. An orthographic projection of the third sub-layer 308-3 on the plane where the display substrate is located includes the orthographic projection of the second sub-layer 308-2 on the plane where the display substrate is located, and an area of the orthographic projection of the third sub-layer 308-3 on the plane where the display substrate is located is greater than the area of the orthographic projection of the second sub-layer 308-2 on the plane where the display substrate is located. The orthographic projection of the third sub-layer 308-3 on the plane where the display substrate is located is located within the orthographic projection of the first sub-layer 308-1 on the plane where the display substrate is located. As shown in FIG. 8L, the multiple film layers of the partition part 308a form an undercut structure.

A material of the first sub-layer 308-1 and the third sub-layer 308-3 may be SiOₓ, and a material of the second sub-layer 308-2 may be SiNₓ. Such a design facilitates a formation of the undercut structure. The patterning process for forming the pattern of the pixel definition layer may include the following four steps.

In the first step, carbon tetrafluoride (CF4) is used to etch the sixth insulation thin film, the seventh insulation thin film, and the eighth insulation thin film, and an etching selection ratio of SiOₓ and SiNₓ is greater than 1.0 and less than 1.5. The etching selection ratio refers to a ratio of an etching rate of one material to another material under a same etching condition.

In the second step, a photoresist layer is formed on a side of the eighth insulation thin film, and an etching gas containing oxygen ions is used to etch the photoresist layer. An orthographic projection of the photoresist layer on the plane where the display substrate is located is located within an orthographic projection of the eighth insulation thin film on the plane where the display substrate is located, and the photoresist layer exposes a portion of a surface of the eighth insulation thin film away from the seventh insulation thin film.

In the third step, carbon tetrafluoride (CF4) is used to etch the eighth insulation thin film that is not covered by the photoresist layer. The etching selection ratio of SiOₓ to SiNₓ is greater than 1.0 and less than 1.5.

In the fourth step, sulfur hexafluoride (SF6) is used for etching. The etching selection ratio of SiNₓ to SiOₓ is greater than 6, and an etching rate of SiNₓ is much greater than an etching rate of SiOₓ, so the undercut structure may be formed.
(23) Forming a pattern of an organic emitting layer. Forming the pattern of the organic emitting layer may include depositing an organic emitting thin film on a side of the base substrate 101 on which the aforementioned patterns are formed, and patterning the organic emitting thin film by a patterning process to form the pattern of the organic emitting layer, as shown in FIG. 8M.

As shown in FIG. 8M, the pattern of the organic emitting layer may include a first organic emitting layer 301-3, a second organic emitting layer 302-5, and a third organic emitting layer 303-7. The first organic emitting layer 301-3 may be located within the opening area of the first sub-pixel P1, the second organic emitting layer 302-5 may be located within the opening area of the second sub-pixel P2, and the third organic emitting layer 303-7 may be located within the opening area of the third sub-pixel P3.
(24) Forming a pattern of a cathode layer. Forming the pattern of the cathode layer may include depositing an eleventh conductive thin film on a side of the base substrate 101 on which the aforementioned patterns are formed, and patterning the eleventh conductive thin film by a patterning process to form the pattern of the cathode layer, as shown in FIG. 8N.

As shown in FIG. 8N, the pattern of the cathode layer may include a second electrode 301-2, a fourth electrode 302-4, and a sixth electrode 303-6. By way of example, the second electrode 301-2, the fourth electrode 302-4, and the sixth electrode 303-6 may be an integral structure interconnected.

An embodiment of the present disclosure further provides a display apparatus. The display apparatus includes the display substrate described in any of the above embodiments. The display apparatus may be any product or component with a display function, such as electronic paper, a mobile phone, a tablet computer, a television, a display, a notebook computer, a digital photo frame, and a navigator. However, this is not limited in an embodiment of the present disclosure.

Although the embodiments disclosed in the present disclosure are described as above, the described contents are only embodiments which are adopted in order to facilitate understanding of the present disclosure, and are not intended to limit the present disclosure. It should be noted that the above implementations or embodiments are exemplary only and not restrictive. Therefore, the present disclosure is not limited to what is specifically shown and described herein. Various modifications, substitutions or omissions may be made in forms and details of implementation modes without departing from the scope of the present disclosure.

1. A display substrate, comprising a base substrate and a light emitting structure layer located on a side of the base substrate, wherein the light emitting structure layer comprises a reflection layer and a light emitting composite layer stacked sequentially in a direction away from the base substrate, the reflection layer has a plurality of first vias, and the light emitting composite layer comprises a first light emitting device, a second light emitting device, and a third light emitting device arranged sequentially;
wherein the light emitting structure layer further comprises a first conductive structure, and the first conductive structure is located between the light emitting composite layer and the base substrate, and the first light emitting device is in contact with at least a portion of a surface of the first conductive structure away from the base substrate; at least a portion of the first conductive structure is located within a first via; in a thickness direction of the display substrate, the first conductive structure comprises at least two sections, an orthographic projection of a section close to the light emitting composite layer on a plane where the display substrate is located is located within an orthographic projection of a section adjacent to the section and away from the light emitting composite layer on the plane where the display substrate is located, and an area of the orthographic projection of the section close to the light emitting composite layer on the plane where the display substrate is located is less than an area of the orthographic projection of the section adjacent to the section and away from the light emitting composite layer on the plane where the display substrate is located.

2. The display substrate according to claim 1, comprising a plurality of sub-pixels, wherein the plurality of sub-pixels comprise at least a first sub-pixel, a second sub-pixel, and a third sub-pixel; the first sub-pixel comprises the first light emitting device and is configured to emit light of a first color, the second sub-pixel comprises a second light emitting device and is configured to emit light of a second color, the third sub-pixel comprises a third light emitting device and is configured to emit light of a third color, and each of the first color, the second color, and the third color is one of three primary colors;
wherein the light emitting structure layer further comprises a micro-cavity adjustment layer, the micro-cavity adjustment layer is located between the reflection layer and the light emitting composite layer, and the micro-cavity adjustment layer is configured such that the first sub-pixel, the second sub-pixel, and the third sub-pixel have different micro-cavity cavity lengths.

3. The display substrate according to claim 2, wherein the micro-cavity adjustment layer comprises a first adjustment part, a second adjustment part, and a third adjustment part arranged sequentially; the first adjustment part is configured such that the first sub-pixel has a first micro-cavity cavity length H1 and the first adjustment part has a first thickness h1; the second adjustment part is configured such that the second sub-pixel has a second micro-cavity cavity length H2 and the second adjustment part has a second thickness h2; the third adjustment part is configured such that the third sub-pixel has a third micro-cavity cavity length H3 and the third adjustment part has a third thickness h3;
wherein H1>H2>H3, and h1>h2>h3.

4. The display substrate according to claim 3, wherein a thickness of the third adjustment part ranges from 200 angstroms to 600 angstroms.

5. The display substrate according to claim 4, wherein a thickness of the first adjustment part ranges from 1300 angstroms to 1700 angstroms and a thickness of the second adjustment part ranges from 1200 angstroms to 1600 angstroms.

6. The display substrate according to claim 2, wherein the micro-cavity adjustment layer has a plurality of second vias and the plurality of second vias are provided in one-to-one correspondence with and in communication with the plurality of first vias;
the first conductive structure comprises two sections, the two sections are a first section and a second section respectively, and the second section is closer to the light emitting composite layer than the first section, the first section is located within a first via, and the second section is located within a second via.

7. The display substrate according to claim 6, wherein an orthographic projection of the first section on the plane where the display substrate is located has a first outer edge, and an orthographic projection of the second section on the plane where the display substrate is located has a second outer edge;
wherein the first outer edge surrounds the second outer edge, there is a gap between the first outer edge and the second outer edge, and a range of the gap is greater than or equal to 0.04 micron and less than or equal to 0.1 micron.

8. The display substrate according to claim 6, wherein an orthographic projection of the second section on the plane where the display substrate is located coincides with an orthographic projection of the second via on the plane where the display substrate is located; or
wherein a surface of the first section away from the base substrate is flush with a surface of the reflection layer away from the base substrate; or, a surface of the first section away from the base substrate is closer to the base substrate than a surface of the reflection layer away from the base substrate.

9. (canceled)

10. The display substrate according to claim 2, wherein the micro-cavity adjustment layer comprises a first adjustment part, a second adjustment part, and a third adjustment part arranged sequentially, and thicknesses of the first adjustment part, the second adjustment part, and the third adjustment part are different;
the second adjustment part has a plurality of second vias, the plurality of second vias are provided in one-to-one correspondence with and in communication with the plurality of first vias; the light emitting structure layer further comprises a second conductive structure, the second conductive structure is located between the light emitting composite layer and the base substrate, and the second light emitting device is in contact with at least a portion of a surface of the second conductive structure away from the base substrate; at least a portion of the second conductive structure is located within a first via.

11. The display substrate according to claim 3, wherein the first light emitting device comprises a first electrode, a first organic emitting layer, and a second electrode which are stacked, and the first electrode is closer to the base substrate than the second electrode; wherein at least a portion of the first electrode is located on a side of the micro-cavity adjustment layer away from the base substrate.

12. The display substrate according to claim 11, wherein the micro-cavity adjustment layer has a plurality of second vias and the plurality of second vias are provided in one-to-one correspondence with and in communication with the plurality of first vias; the first electrode comprises a first portion and a second portion that are connected; the first portion is located on a side of the micro-cavity adjustment layer away from the base substrate and the second portion is located within a second via.

13. The display substrate according to claim 12, wherein a thickness of the second portion is greater than or equal to 30% of a thickness of the first portion and less than or equal to the thickness of the first portion in a radial direction of the second via; or
wherein a size of the second portion in the thickness direction of the display substrate does not exceed 50% of an aperture depth of the second via.

14. (canceled)

15. The display substrate according to claim 12, wherein the first electrode further comprises a third portion, the third portion is located on a side of the micro-cavity adjustment layer away from the base substrate, and the third portion and the first portion are respectively located on two opposite sides of the second portion.

16. The display substrate according to claim 15, wherein an orthographic projection of the third portion on the plane where the display substrate is located has a size range in a radial direction of the second via greater than or equal to 0.04 micron and less than or equal to 0.1 micron; or
wherein the light emitting structure layer further comprises an isolation layer, the isolation layer is located within a first via, and the isolation layer is provided around the first conductive structure; an edge of an orthographic projection of the third portion on the plane where the display substrate is located close to the second light emitting device is located within a range of an orthographic projection of the isolation layer on the plane where the display substrate is located.

17. (canceled)

18. The display substrate according to claim 15, wherein the second light emitting device comprises a third electrode, a second organic emitting layer, and a fourth electrode which are stacked, and the third electrode is closer to the base substrate than the fourth electrode;
wherein there is a gap between an orthographic projection of the third portion on the plane where the display substrate is located and an orthographic projection of the third electrode on the plane where the display substrate is located, and a range of the gap is greater than or equal to 0.2 micron, and less than or equal to 0.5 micron.

19. The display substrate according to claim 18, wherein the gap is greater than a difference between an aperture of the first via and an aperture of the second via; or
wherein an orthographic projection of the third portion on the plane where the display substrate is located is located within an orthographic projection of the first adjustment part on the plane where the display substrate is located, and an orthographic projection of the third electrode on the plane where the display substrate is located is located within an orthographic projection of the second adjustment part on the plane where the display substrate is located.

20. (canceled)

21. The display substrate according to claim 3, wherein the light emitting structure layer further comprises an isolation layer, the isolation layer is located within the first via, and the isolation layer is provided around the first conductive structure.

22. The display substrate according to claim 21, wherein a surface of the isolation layer away from the base substrate is flush with a surface of the reflection layer away from the base substrate.

23. The display substrate according to claim 21, wherein a range of a ring width of the isolation layer is greater than or equal to 0.2 micron and less than or equal to 0.3 micron; or
wherein the third thickness is greater than a maximum value of a ring width of the isolation layer.

24. (canceled)

25. A display apparatus, comprising the display substrate according to claim 1.
